(19) United States
(12) Patent Application Publication
(10) Pub. No.: US 2015/0241779 A1
(43) Pub. Date: Aug. 27, 2015

(54) REAGENT FOR ENHANCING GENERATION OF CHEMICAL SPECIES

(71) Applicant: TOYO GOSEI CO., LTD., Inzai-shi (JP)

(72) Inventor: Satoshi Enomoto, Inzai-shi (JP)

(21) Appl. No.: 14/626,821

(22) Filed: Feb. 19, 2015

Related U.S. Application Data
(60) Provisional application No. 61/943,159, filed on Feb. 21, 2014.

(51) Int. Cl. G03F 7/20; G03F 7/004

(52) U.S. Cl. CPC G03F 7/203; G03F 7/2002; G03F 7/004

(57) ABSTRACT

A reagent that enhances acid generation of a photoacid generator and composition containing such reagent is described.

### CROSS-REFERENCE TO RELATED APPLICATION

This application claims the benefit under 35 U.S.C. §119(e) of U.S. Provisional Patent Application Ser. No. 61/943,159 filed on Feb. 21, 2014, the disclosure of which is hereby incorporated herein in its entirety by this reference.

### TECHNICAL FIELD

Several aspects of the disclosure relate to the fields of reagents or chemical agents formed from such reagents enhancing a generation of a chemical species such as acid and base. Such chemical agent also enhances generation of a chemical species as an acid generation enhancer (AGE) or photosensitizer.

### BACKGROUND

Current high-resolution lithographic processes are based on chemically amplified resists (CARs) and are used to pattern features with dimensions less than 100 nm.

A method for forming pattern features with dimensions less than 100 nm is disclosed in U.S. Pat. No. 7,851,252 (filed on Feb. 17, 2009), the contents of which are incorporated herein by this reference.

### BRIEF SUMMARY

A chemical agent relating to an aspect of the disclosure is characterized by that: a first interaction of a chemical agent with a precursor occurs such that the chemical agent donates at least one of electron and energy to the precursor or the chemical agent accepts at least one of electron and energy from the precursor; and a generation of a chemical species from the precursor is enhanced by the first interaction.

With regard to the chemical agent, it is preferred that the chemical species is acid.

With regard to the chemical agent, it is preferred that the chemical agent is a ketyl radical.

With regard to the chemical agent, it is preferred that the chemical agent has at least one aryl group.

With regard to the chemical agent, it is preferred that the at least one aryl group has at least one electron-donating substituent.

It is preferred that at least one of such electron-donating groups is positioned at a para or ortho position of the benzene ring. Typical examples of such electron-donating group are an alkyl group, aryl group, alkoxy group, aryloxy group, alkyl amino group, aryl amino group, hydroxyl group, alkyl thio group and aryl thio group.

With regard to the chemical agent, it is preferred that the chemical agent is converted to a first product through the first interaction.

With regard to the chemical agent, a second interaction of the chemical agent with a first additive may occur.

With regard to the chemical agent, it is preferred that the first interaction inhibits the second interaction or the first interaction supersedes the second interaction.

With regard to the chemical agent, the second interaction may be accompanied with an encounter of the chemical agent and the first additive.

With regard to the chemical agent, the first interaction may be a long-range interaction. Examples of such long-range interaction are electron transfer and energy transfer, which take place without molecular encounter.

With regard to the chemical agent, the second interaction may be a short-range interaction. An example of such short-range interaction is bimolecular reaction. For example, the second interaction may result in abstraction of a hydrogen atom of the first additive.

With regard to the chemical agent, it is preferred that the chemical agent does not donate an electron or energy to the first additive.

With regard to the chemical agent, it is preferred that a number of multiple bonds contained in the first product are greater than a number of multiple bonds contained in the chemical agent.

With regard to the chemical agent, it is preferred that the first additive suppresses diffusion of the chemical species.

With regard to the chemical agent, a typical example of the first additive is a base such as amine.

With regard to the chemical agent, it is preferred that the chemical agent in its ground state donates an electron to the precursor.

A reagent relating to an aspect of this disclosure is characterized wherein the reagent generates the chemical agent explained above.

With regard to the reagent, it is preferred that the reagent has its hydrogen atom abstracted to generate the chemical agent.

With regard to the reagent, it is preferred that the reagent has its hydrogen atom abstracted by a radical generated by at least one of a first electromagnetic ray and a first particle ray.

With regard to the reagent, it is preferred that the reagent has its hydrogen atom abstracted by a radical generated by at least one of a EUV light and an electron beam.

A composition relating to an aspect of this disclosure includes: a first reagent and a precursor. It is preferred that a generation of a chemical species from the precursor is capable of occurring and the generation of the chemical species is capable of being enhanced by a first interaction of the precursor with at least one of the first reagent and a first chemical agent generated from the first reagent.

With regard to the composition, it is preferred that the precursor and the chemical species are photoacid generator and acid, respectively. Such composition may further include a resin having acid-dissociable groups. In such case, typically, the content of the acid generator in the composition is 0.1 to 20 parts by mass with respect to 100 parts by mass of such resin. Preferably, such composition may include 0.5 to 10 parts by mass of PAG with respect to 100 parts by mass of such resin. Such composition can exhibit good sensitivity and developability. If the content of the acid generator is less than 0.1 parts by mass, the sensitivity and the developability of the resist material may decrease.

With regard to the composition, it is preferred that the first interaction is a long-range interaction.

With regard to the composition, it is preferred that the first interaction is at least one of electron transfer and energy transfer.

With regard to the composition, it is preferred that the composition further includes a first additive.

With regard to the composition, it is preferred that the first additive is capable of suppressing diffusion of the chemical species. An example of such first additive is quencher, which suppresses diffusion of such chemical species such as acid in an irradiated area of a film formed by application of such composition. Such quencher can contribute to suppression of penetration of such chemical species into undesired areas to improve pattern resolution. Acid can be generated from PAG by exposure of such film to an electromagnetic ray or a particle ray. Moreover, such quencher can improve storage stability of such composition and reduction of the change of line width in post-exposure delay because such quencher can trap such chemical species.

In the event that such composition includes a resin having acid-dissociable groups, the content of such quencher is 15 parts by mass or less, preferably 10 parts by mass or less, and still more preferably 5 parts by mass or less, with respect to 100 parts by mass of such resin. If the amount of such quencher is more than 15 parts by mass, the sensitivity may decrease. If the amount of such quencher is less than 0.001 parts by mass, the shape or the dimensional accuracy of the resist pattern may deteriorate depending on the process conditions. A nitrogen-containing organic compound such as amine or a photodegradable base is preferably used as such quencher. Only one kind of quencher or a plurality of kinds of quencher can be used for improvement of the performance of such composition. A typical example of such photodegradable base is an onium salt compound that exhibits acid diffusion controllability by decomposing with a light irradiation. Specific examples of such sulfonium salt compound and iodonium salt compound are triphenyl sulfonium benzoate and diphenyl iodonium acetate, respectively.

With regard to the composition, it is preferred that the composition includes a compound that is capable of reacting with the chemical species.

With regard to the composition, it is preferred that the composition includes a compound that is at least one group that is capable of being decomposed by the chemical species.

With regard to the composition, it is preferred that the composition includes a second additive that acts as a surfactant agent.

The surfactant can improve the applicability, striation, developability, and the like. Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate; commercially available products such as KP341 (manufactured by Shin-Etsu Chemical Co., Ltd.), Polyflow No. 75, Polyflow No. 95 (manufactured by Kyoeisha Chemical Co., Ltd.), EFTOP EF301, EFTOP EF303, EFTOP EF352 (manufactured by JEMCO, Inc.), Megafac F171, Megafac F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.); and the like. These surfactants may be used either individually or in combination. The surfactant is normally used in an amount of 2 parts by mass or less based with respect to 100 parts by mass of a resin having acid-dissociable groups.

With regard to the composition, it is preferred to have a third additive that acts as a dissolution inhibitor. Such dissolution inhibitor can inhibit dissolution of unexposed parts of a film while promoting dissolution of exposed parts of the film. Dissolution inhibitor may be carboxylic acid, ketone or ester. A compound having an acid-dissociable group can also be used as dissolution inhibitor. Dissolution inhibitor having alicyclic and aromatic groups can improve the dry etching resistance of the film, the pattern shape, adhesion to a substrate, or the like. Compounds having an adamantyl group are the following examples of such dissolution inhibitor: 1-adamantanecarboxylic acid, 2-adamantanone, t-butyl-1-adamantanecarboxylate, t-butoxycarbonylmethyl 1-adamantanecarboxylate, 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, and 2,5-dimethyl-2,5-di(adamantylcarbonyloxy)hexane; deoxycholates such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate; alkyl carboxylates such as dimethyl adipate, diethyl adipate, dipropyl adipate, di-n-butyl adipate, and di-t-butyl adipate; 3-(2-hydroxy-2,2-bis(trifluoromethyl)ethyetetracyclo[6.2.1.13, 6.02, 7]dodecane; and the like. Specific examples of such dissolution inhibitor having an aromatic group include phenoxy derivatives such as 1-adamantantyl oxy carbonyl benzene, t-butoxycarbonylmethyl phenol, 2,7-di-t-butyl oxy naphthalene and [3-(2-methyl-adamantan-2-yl) carbonylmethoxy-phenoxy]-acetic acid 2-methyl-adamantan-2-yl ester and the like. Only one kind of dissolution inhibitor and a plurality of kinds of dissolution inhibitors can be used for improvement of performance of such composition. A typical amount of such dissolution inhibitor is 50 parts by mass or less, and preferably 30 parts by mass or less, with respect to 100 parts by mass of resin having acid-dissociable groups. If the amount of such dissolution inhibitor is more than 50 parts by mass, the heat resistance of the film may decrease.

Examples of other additives include a dye or a pigment that visualizes a latent image in the exposed area to reduce the effects of halation during exposure, an adhesion improver that improves adhesion to a substrate, an alkali-soluble resin, a low-molecular-weight alkali solubility controller that includes an acid-dissociable protecting group, a halation inhibitor, a preservative, an antifoaming agent, and the like.

With regard to the composition, it is preferred that the generation of chemical species is capable of being enhanced by the first chemical agent.

With regard to the composition, it is preferred that the first chemical agent is capable of donating an electron to the precursor.

With regard to the composition, it is preferred that the first chemical agent is capable of being oxidized by donating the electron to the precursor.

With regard to the composition, it is preferred that the first chemical agent is capable of reacting with the first additive.

With regard to the composition, it is preferred that the first chemical agent is capable of reacting with the first additive through a second interaction of the first additive and at least one of the first reagent and the first chemical agent.

With regard to the composition, it is preferred that the second interaction is a short-range interaction.

With regard to the composition, it is preferred that the first chemical agent is capable of abstracting a hydrogen atom of the first additive.

With regard to the composition, it is preferred that the first additive is capable of reacting with the chemical species.

With regard to the composition, it is preferred that the first additive is base such as amine.

With regard to the composition, it is preferred that the first interaction is capable of occurring by exciting at least one of the first reagent and the first chemical agent.

With regard to the composition, it is preferred that the first chemical agent is a ketyl radical.

With regard to the composition, it is preferred that the first chemical agent is a ketone.

With regard to the composition, it is preferred that the first chemical agent acts as a photosensitizer.

With regard to the composition, it is preferred that the composition includes a second reagent and the generation of the chemical species is capable of being enhanced by a third interaction of the precursor with at least one of the second reagent and a second chemical agent generated from the second reagent.

With regard to the composition, it is preferred that the second chemical agent is capable of enhancing the generation of the chemical species.

With regard to the composition, it is preferred that the composition further includes: a second reagent; the generation of the chemical species is capable of being enhanced by a third interaction of the precursor with at least one of the second reagent and a second chemical agent generated from the second reagent; and the first interaction is an interaction between the precursor and the first chemical agent in its ground state.

With regard to the composition, it is preferred that the third interaction is an interaction between the precursor and the second chemical agent.

With regard to the composition, it is preferred that the second reagent acts as a photosensitizer.

A polymer relating to an aspect of the disclosure includes: a first moiety that is capable of reacting with a chemical species; a second moiety that is capable of enhancing a generation of the chemical species through a first interaction of at least one of the second moiety and a fourth moiety converted from the second moiety with a precursor capable of generating the chemical species.

With regard to the polymer, it is preferred that the chemical species is acid; and the first interaction is at least one of an electron transfer and an energy transfer.

A polymer relating to an aspect of this disclosure includes: a first moiety that is capable of reacting with a chemical species; a second moiety; and a third moiety that is capable of generating the chemical species, wherein the second moiety is capable of enhancing a generation of the chemical species through a first interaction of at least one of the second moiety and a fourth moiety converted from the second moiety with the third moiety.

With regard to the polymer, it is preferred that diffusion of the chemical species is capable of being suppressed by a first additive.

With regard to the polymer, it is preferred that the first additive is capable of reacting with the at least one of the second moiety and the fourth moiety through a second interaction between the first additive and the at least one of the second moiety and the fourth moiety.

With regard to the polymer, it is preferred that the polymer includes a fifth moiety and the fifth moiety is capable of enhancing a generation of the chemical species through a third interaction of at least one of the fifth moiety and a sixth moiety converted from the fifth moiety with the third moiety.

With regard to the polymer, it is preferred that the polymer includes a fifth moiety and the fifth moiety is capable of enhancing a generation of the chemical species through a third interaction of at least one of the fifth moiety and a sixth moiety converted from the fifth moiety with the third moiety. With regard to the polymer, it is preferred that the polymer includes a fifth moiety and the fifth moiety is capable of enhancing a generation of the chemical species through a third interaction of at least one of the fifth moiety and a sixth moiety converted from the fifth moiety with the third moiety.

With regard to the polymer, it is preferred that the third interaction is at least one of an electron transfer and an energy transfer.

With regard to the polymer, it is preferred that the first interaction is an electron transfer from the fourth moiety in its ground state to the third moiety.

With regard to the polymer, it is preferred that the third interaction is an electron transfer from the sixth moiety in its excited state to the third moiety.

A method of manufacturing a device relating to an aspect of the disclosure includes: forming a film containing one of the above compositions; and first exposing the film to at least one of a first electromagnetic ray and a first particle ray.

Typical examples of such device are integrated circuit, optical element and electro-optical element such as display element.

With regard to the method, it is preferred that the first interaction occurs in the first exposing of the film.

With regard to the method, it is preferred that the method further includes second exposing the film to at least one of a second electromagnetic ray and a second particle ray.

With regard to the method, it is preferred that the first interaction occurs in the second exposing of the film.

With regard to the method, it is preferred that the first electromagnetic ray and the first particle ray are a EUV light and an electron beam, respectively.

With regard to the method, it is preferred that the second electromagnetic ray is a UV light or a visible light.

A method of manufacturing a device relating to an aspect of this disclosure includes: forming a film containing any one of the polymers explained above; and first exposing the film to at least one of a first electromagnetic ray and a first particle ray.

With regard to the method, it is preferred that the first interaction occurs in the first exposing of the film.

With regard to the method, it is preferred that the method further includes second exposing the film to at least one of a second electromagnetic ray and a second particle ray.

With regard to the method, it is preferred that the first interaction occurs in the second exposing of the film.

With regard to the method, it is preferred that the first electromagnetic ray and the first particle ray are a EUV light and an electron beam, respectively.

With regard to the method, it is preferred that the second electromagnetic ray is a UV light or a visible light.

A method relating to an aspect of this disclosure includes: forming a film containing a composition; first exposing the film to at least one of a first electromagnetic ray and a first particle ray; and second exposing the film to at least one of a second electromagnetic ray and a second particle ray. With regard to the method, it is preferred that the composition includes a first reagent and a precursor; and a chemical species is generated from the precursor in at least one of the first exposing of the film and the second exposing of the film.

With regard to the method, it is preferred that the first electromagnetic ray and the first particle ray are a EUV light and an electron beam, respectively.

With regard to the method, it is preferred that the second electromagnetic ray is a UV light or a visible light.

With regard to the method, it is preferred that the chemical species is acid.

With regard to the method, it is preferred that the first exposing of the film generates a first chemical agent from the first reagent.

With regard to the method, it is preferred that the first exposing of the film induces a first interaction of the precursor with at least one of the first reagent and the first chemical agent.

With regard to the method, it is preferred that the first interaction occurs such that the first chemical agent donates at least one of electron and energy to the precursor or the first chemical agent accepts at least one of electron and energy from the precursor.

With regard to the method, it is preferred that the first chemical agent is a ketyl radical.

With regard to the method, it is preferred that the first chemical agent is a ketone.

With regard to the method, it is preferred that the first chemical agent has at least one aryl group.

With regard to the method, it is preferred that the at least one aryl group has at least one electron-donating substituent.

With regard to the method, it is preferred that: the first chemical agent absorbs at least one of the second electromagnetic ray and the second particle ray; and the chemical species is generated at least during the second exposing of the film.

With regard to the method, it is preferred that the composition further contains a quencher that traps the chemical species.

With regard to the method, it is preferred that the quencher suppress diffusion of the chemical species.

With regard to the method, it is preferred that the second exposing of the film is carried out by using the second electromagnetic ray.

With regard to the method, it is preferred that the first exposing of the film is carried out such that the film is irradiated with the first electromagnetic ray through a mask.

With regard to the method, it is preferred that the second exposing of the film is carried out such that a portion of the film that has not been exposed to the first electromagnetic ray is irradiated with the second electromagnetic ray.

With regard to the method, it is preferred that a wavelength of the first electromagnetic ray is shorter than that of the second electromagnetic ray.

With regard to the method, it is preferred that the second exposing of the film is carried out without any mask.

With regard to the method, it is preferred that the composition further includes a resin having groups that are to react with the chemical species.

A composition relating to an aspect of the disclosure is used for performing any one of the methods.

### BRIEF DESCRIPTION OF THE DRAWING

In the drawings, which illustrate what is currently considered to be the best mode of carrying out the disclosure:

FIG. 1 shows a fabrication process of an IC.

### DETAILED DESCRIPTION

### Experimental Procedures:

### Synthesis of 1-(4-methoxyphenyl)ethanol (Reagent 1)

5.0 g of 4-methoxyacetophenone and 0.10 g of potassium hydroxide are dissolved in ethanol. 1.04 g of sodium boronhydride is added to the ethanol solution containing 4-methoxyacetophenone and potassium hydroxide. The mixture is added at 25 degrees Celsius for 3 hours. Since then, alkali in the mixture is neutralized by 10% aqueous solution of hydrochloric acid. The organic phase is collected through separation by liquid extraction using 100 g of methylene chloride. The organic phase is washed with water. Thereafter, methylene chloride is distilled away. Thereby, 4.31 g of 1-(4-methoxy-phenyl)ethanol is obtained.

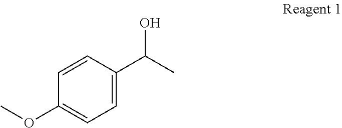

### Synthesis of 2,2′,4-trimethoxybenzophenone

2.50 g of 4′-hydroxy-2,4-dimethoxybenzophenone, 2.44 g of dimethyl sulfate and 2.68 g of potassium carbonate are dissolved in 20.0 g of acetone. The mixture is stirred at reflux temperature for 2 hours. Since then, the mixture is cooled to 25 degrees Celsius and it is further stirred for 10 minutes after addition of 60.0 g of water and a deposit is filtrated. Then, the deposit is dissolved in 30.0 g of ethyl acetate and the organic phase is washed with water. Thereafter, ethyl acetate is distilled away and the resultant is purified by recrystallization using 25.0 g of ethanol. Thereby, 1.60 g of 2,2′,4-trimethoxybenzophenone is obtained.

### Synthesis of (2,4-dimethoxyphenyl)-(4-methoxyphenyl)-dimethoxymethane

7.00 g of 2,2′,4-trimethoxybenzophenone is dissolved in 27.8 g of thionyl chloride. The mixture is stirred at reflux temperature for 5 hours. Since then, thionyl chloride is distilled away and the resultant is dissolved in 15 g of toluene. Then, the prepared solution is added dropwise over 1 hour to 30 g of a methanol solution containing 5.0 g of sodium methoxide at 5 degrees Celsius. After the addition is completed, the mixture is warmed up to 25 degrees Celsius with stirring for 2 hours. Then, the mixture is further stirred after an addition of 50 g of pure water. Then, methanol is distilled away and the resultant is extracted by 35 g of toluene and the organic phase is washed with water. Thereafter, toluene is distilled away. Thereby, 3.87 g of crude (2,4-dimethoxyphenyl)-(4-methoxyphenyl)-dimethoxymethane is obtained as an oil.

### Synthesis of 2-(2,4-dimethoxyphenyl)-2-(4-methoxyphenyl)-1,3-dioxolane (Reagent 2)

3.8 g of crude (2,4-dimethoxyphenyl)-(4-methoxyphenyl)-dimethoxymethane, 0.03 g of camphor sulfonic acid and 2.03 g of ethyleneglycol are dissolved in 5.7 g of tetrahydrofuran. The mixture is stirred at 25 degrees Celsius for 72 hours. Since then, the organic solvent is distilled away and the resultant is dissolved in 11 g of dichloromethane. Then, the mixture is further stirred after addition of 5% aqueous solution of sodium carbonate and the organic phase is washed with 5% aqueous solution of sodium carbonate and water. Thereafter, dichloromethane is distilled away and the residue is purified by silica gel column chromatography (ethyl acetate:hexane:triethylamine=10:90:0.01). Thereby, 2.1 g of (2,4-dimethoxyphenyl)-(4-methoxyphenyl)-1,3-dioxolane is obtained.

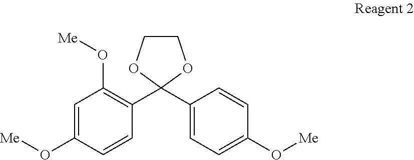 [SMILES: COc1ccc(C2(c3ccc(OC)cc3OC)OCCO2)cc1]

### Synthesis of bis-(4-methoxy-phenyl)-dimethoxymethane

2.0 g of 4,4′-dimethoxy-benzophenone, 0.05 g of bismuth (III) trifluoromethanesulfonate and 5.7 g of trimethyl orthofomate are dissolved in 5.0 g of methanol. The mixture is stirred at reflux temperature for 42 hours. Since then, the mixture is cooled to 25 degrees Celsius and further stirred after addition of 5% aqueous NaHCO₃ solution. Then, the mixture is extracted with 30 g ethyl acetate and the organic phase is washed with water. Thereafter, ethyl acetate is distilled away and the resultant is purified by silica gel column chromatography (ethyl acetate:hexane=1:9). Thereby, 1.71 g of bis-(4-methoxy-phenyl)-dimethoxymethane is obtained.

### Synthesis of bis-(4-methoxy-phenyl)-1,3-dioxolane (Reagent 3)

Synthesis of bis-(4-methoxy-phenyl)-1,3-dioxolane as a target substance is synthesized and obtained according to the synthesis of the Reagent 2 mentioned above, except for using bis-(4-methoxy-phenyl)-dimethoxymethane instead of (2,4-dimethoxyphenyl)-(4-methoxyphenyl)-dimethoxymethane for the synthesis of Reagent 2.

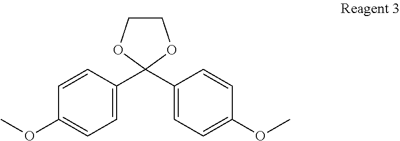

### Synthesis of 2,4-dimethoxy-4′-(2-vinyloxy-ethoxy)-benzophenone

2.00 g of 2,4-dimethoxy-4′-hydroxybenzophenone, 2.48 g of 2-chloroethyl vinyl ether and 3.21 g of potassium carbonate are dissolved in 12.0 g of dimethyl formamide. The mixture is stirred at 110 degrees Celsius for 15 hours. Afterward, the mixture is cooled to 25 degrees Celsius and it is further stirred after addition of 60.0 g of water, then extracted with 24.0 g toluene and the organic phase is washed with water. Thereafter, toluene is distilled away. Thereby, 3.59 g of 2,4-dimethoxy-4′-(2-vinyloxy-ethoxy)-benzophenone is obtained.

### Synthesis of 2,4-dimethoxy-4′-(2-hydroxy-ethoxy)-benzophenone

3.59 g of 2,4-dimethoxy-4′-(2-vinyloxy-ethoxy)-benzophenone, 0.28 g of pyridinium p-toluenesulfonate and 2.1 g of water are dissolved in 18.0 g of acetone. The mixture is stirred at 35 degrees Celsius for 12 hours. Afterward, the mixture is further stirred after addition of 3% aqueous solution of sodium carbonate, then extracted with 28.0 g ethyl acetate and the organic phase is washed with water. Thereafter, ethyl acetate is distilled away. Thereby, 3.04 g of 2,4-dimethoxy-4′-(2-hydroxy-ethoxy)-benzophenone is obtained.

### Synthesis of 2,4-dimethoxy-4′-(2-acetoxy-ethyl)-benzophenone

3.0 g of 2,4-dimethoxy-4′-(2-hydroxy-ethoxy)-benzophenone and 1.1 g of acetic anhydride are dissolved in 21 g of tetrahydrofuran. 1.2 g of triethylamine dissolved in 3.6 g of tetrahydrofuran is added dropwise to the tetrahydrofuran solution containing 2,4-dimethoxy-4′-(2-hydroxy-ethoxy)-benzophenone over 10 minutes. After that, the mixture is stirred at 25 degrees Celsius for 3 hours. Afterward, the mixture is further stirred after addition of water, then extracted with 30 g ethyl acetate and the organic phase is washed with water. Thereafter, ethyl acetate is distilled away, and the residue is purified by silica gel column chromatography (ethyl acetate:hexane=1:9). Thereby, 2.72 g of 2,4-dimethoxy-4′-(2-acetoxy-ethyl)-benzophenone is obtained.

### Synthesis of (2,4-dimethoxyphenyl)-[4′-(2-hydroxy-ethoxy)-phenyl]-dimethoxymethane

Synthesis of (2,4-dimethoxyphenyl)-[4′-(2-hydroxy-ethoxy)-phenyl]-dimethoxymethane as a target substance is synthesized and obtained according to the synthesis of (2,4-dimethoxyphenyl)-(4-methoxyphenyl)-dimethoxymethane mentioned above, except for using 2,4-dimethoxy-4′-(2-acetoxy-ethyl)-benzophenone instead of 2,2′,4-trimethoxybenzophenone for the synthesis of (2,4-dimethoxyphenyl)-(4-methoxyphenyl)-dimethoxymethane.

### Synthesis of (2,4-dimethoxyphenyl)-[4′-(2-hydroxy-ethoxy)-phenyl]-1,3-dioxolane

Synthesis of (2,4-dimethoxyphenyl)-[4′-(2-hydroxy-ethoxy)-phenyl]-1,3-dioxolane as a target substance is synthesized and obtained according to the synthesis of Reagent 2 mentioned above, except for using (2,4-dimethoxyphenyl)-[4′-(2-hydroxy-ethoxy)-phenyl]-dimethoxymethane instead of (2,4-dimethoxyphenyl)-(4-methoxyphenyl)-dimethoxymethane for the synthesis of Reagent 2.

### (2,4-dimethoxyphenyl)-[4′-(2-methacyloxy-ethoxy)-phenyl]-1,3-dioxolane (Monomer 1)

Synthesis of (2,4-dimethoxyphenyl)-[4′-(2-methacyloxy-ethoxy)-phenyl]-1,3-dioxolane as a target substance is synthesized and obtained according to the synthesis of the 2,4-dimethoxy-4′-(2-acetoxy-ethyl)-benzophenone mentioned above, except for using methacrylic anhydride instead of acetic anhydride for the synthesis of 2,4-dimethoxy-4′-(2-acetoxy-ethyl)-benzophenone.

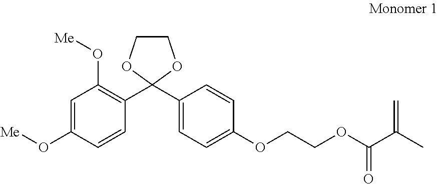 [SMILES: C=C(C)C(=O)OCCOc1ccc(C2(c3ccc(OC)cc3OC)OCCO2)cc1]

### Synthesis of 1-[4-(2-vinyloxy-ethoxy)-phenyl]-ethanone

Synthesis of 1-[4-(2-vinyloxy-ethoxy)-phenyl]-ethanone as a target substance is synthesized and obtained according to the synthesis of the 2,4-dimethoxy-4′-(2-vinyloxy-ethoxy)-benzophenone mentioned above, except for using 4-hydroxy-acetophenone instead of 2,4-dimethoxy-4′-hydroxybenzophenone for the synthesis of 2,4-dimethoxy-4′-(2-vinyloxy-ethoxy)-benzophenone.

### Synthesis of 1-[4-(2-hydroxy-ethoxy)-phenyl]-ethanone

Synthesis of 1-[4-(2-hydroxy-ethoxy)-phenyl]-ethanone as a target substance is synthesized and obtained according to the synthesis of the 2,4-dimethoxy-4′-(2-hydroxy-ethoxy)-benzophenone mentioned above, except for using 1-[4-(2-vinyloxy-ethoxy)-phenyl]-ethanone instead of 2,4-dimethoxy-4′-(2-vinyloxy-ethoxy)-benzophenone for the synthesis of 2,4-dimethoxy-4′-(2-hydroxy-ethoxy)-benzophenone.

### Synthesis of 2-methyl-acrylic acid 2-(4-acetyl-phenoxy)-ethyl ester

Synthesis of 2-methyl-acrylic acid 2-(4-acetyl-phenoxy)-ethyl ester as a target substance is synthesized and obtained according to the synthesis of 2,4-dimethoxy-4′-(2-acetoxy-ethyl)-benzophenone mentioned above, except for using 1-[4-(2-hydroxy-ethoxy)-phenyl]-ethanone and methacrylic anhydride instead of 2,4-dimethoxy-4′-(2-hydroxy-ethoxy)-benzophenone and acetic anhydride, respectively, for synthesis of 2,4-dimethoxy-4′-(2-acetoxy-ethyl)-benzophenone.

### Synthesis of 2-methyl-acrylic acid 2-[4-(1-hydroxy-ethyl)-phenoxy]-ethyl ester (Monomer 2)

3.0 g of 2-methyl-acrylic acid 2-(4-acetyl-phenoxy)-ethyl ester is dissolved in 24.0 g of tetrahydrofuran. 0.92 g of sodium boron hydride dissolved in water is added to the tetrahydrofuran solution. The mixture is stirred at 25 degrees Celsius for 2 hours. Afterward, the mixture is added to the 60 g of water, then extracted with 20.0 g ethyl acetate and the organic phase is washed with water. Thereafter, ethyl acetate is distilled away. Thereby, 2.5 g of 2-methyl-acrylic acid 2-[4-(1-hydroxy-ethyl)-phenoxy]-ethyl ester is obtained.

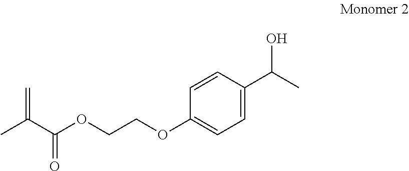 [SMILES: C=C(C)C(=O)OCCOc1ccc(C(C)O)cc1]

### Synthesis of (3-tert-butoxycarbonylmethoxy-phenoxy)-acetic acid tert-butyl ester (DI-A)

3.00 g of resorcinol, 16.5 g of chloroacetic acid 2-methyl-adamantan-2-yl ester and 7.53 g of potassium carbonate are dissolved in 24.0 g of acetone. The mixture is stirred at reflux temperature for 15 hours. Afterward, the mixture is cooled to 25 degrees Celsius and it is further stirred for 10 minutes after addition of 60.0 g of water and acetone is distilled away, then extracted with 36.0 g ethyl acetate and the organic phase is washed with water. Thereafter, ethyl acetate is distilled away, and the resultant is purified by silica gel column chromatography (ethyl acetate:hexane=2:8). Thereby, 8.85 g of [3-(2-methyl-adamantan-2-yl) carbonylmethoxy-phenoxy]-acetic acid 2-methyl-adamantan-2-yl ester is obtained.

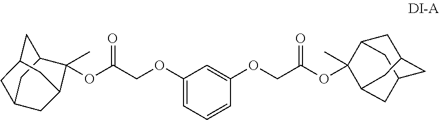 [SMILES: CC1(OC(=O)COc2cccc(OCC(=O)OC3(C)C4CC5CC(C4)CC3C5)c2)C2CC3CC(C2)CC1C3]

A solution containing 5.0 g of α-methacryloyloxy-γ-butylolactone, 6.03 g of 2-methyladamantane-2-methacrylate, and 4.34 g of 3-hydroxyadamantane-1-methacrylate, 0.51 g of dimethyl-2,2′-azobis(2-methylpropionate) and 26.1 g of tetrahydrofuran is prepared. The prepared solution is added dropwise over 4 hours to 20.0 g of tetrahydrofuran placed in flask with stirring and boiling. After the addition of the prepared solution, the mixture is heated to reflux for 2 hours and cooled to room temperature. Addition of the mixture by drops to a mixed liquid containing 160 g of hexane and 18 g of tetrahydrofuran while vigorously stirring precipitates the copolymer. The copolymer is isolated by filtration. Purification of the copolymer is carried out by vacuum drying following two washings by 70 g of hexane, and, thereby, 8.5 g of white powder of the copolymer is obtained.

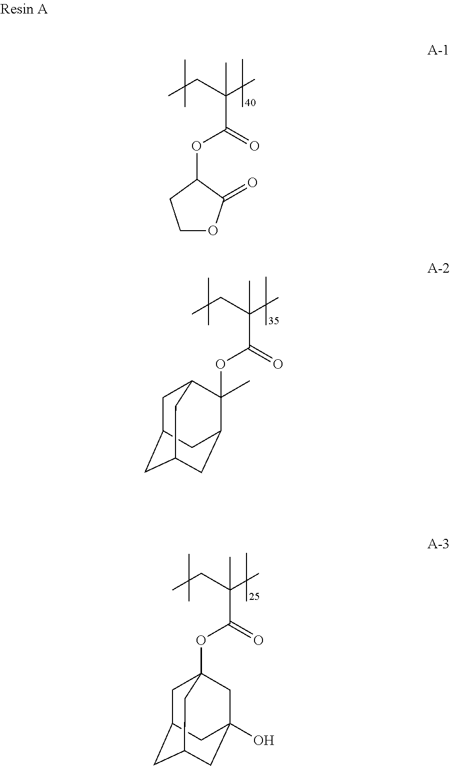 [SMILES: CCC(C)(C)C(=O)OC1CCOC1=O ; CCC(C)(C)C(=O)OC1(C)C2CC3CC(C2)CC1C3 ; CCC(C)(C)C(=O)OC12CC3CC(CC(O)(C3)C1)C2]

A solution containing 0.80 g of Monomer 1, 3.8 g of α-methacryloyloxy-γ-butylolactone, 2.9 g of 2-methyladamantane-2-methacrylate, 2.8 g of 3-hydroxyadamantane-1-methacrylate, 0.13 g of butyl mercaptane, 0.56 g of dimethyl-2,2′-azobis(2-methylpropionate) and 12.1 g of tetrahydrofuran is prepared. The prepared solution is added dropwise over 4 hours to 4.2 g of tetrahydrofuran placed in flask with stirring and boiling under nitrogen atmosphere. After the addition of the prepared solution, the mixture is heated to reflux for 2 hours and cooled to room temperature. Addition of the mixture by drops to a mixed liquid containing 107 g of hexane and 11 g of tetrahydrofuran while vigorously stirring precipitates the copolymer. The copolymer is isolated by filtration. Purification of the copolymer is carried out by vacuum drying following two washings by 37 g of hexane, and, thereby, 6.21 g of white powder of the copolymer (Resin B) is obtained.

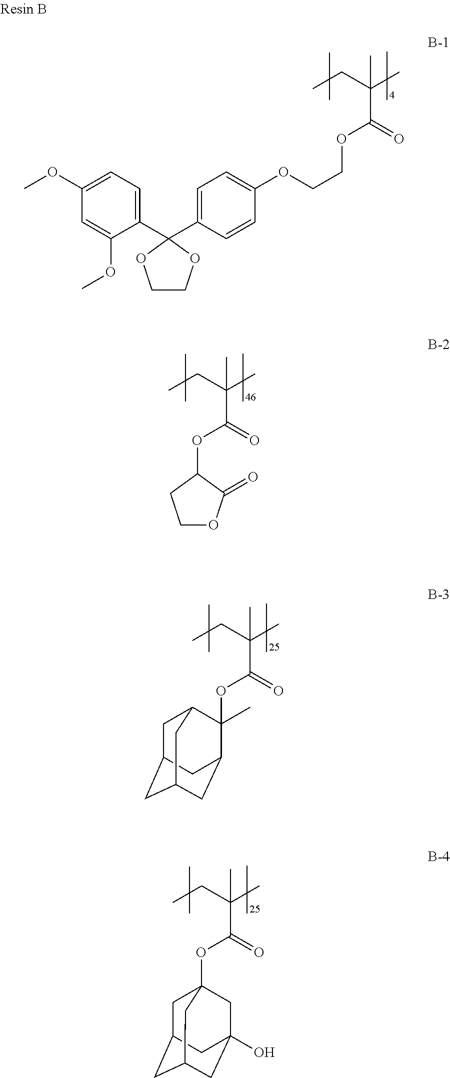 [SMILES: CCC(C)(C)C(=O)OCCOc1ccc(C2(c3ccc(OC)cc3OC)OCCO2)cc1 ; CCC(C)(C)C(=O)OC1CCOC1=O ; CCC(C)(C)C(=O)OC1(C)C2CC3CC(C2)CC1C3 ; CCC(C)(C)C(=O)OC12CC3CC(CC(O)(C3)C1)C2]

A solution containing 0.80 g of Monomer 1, 0.49 g of Monomer 2, 3.9 g of α-methacryloyloxy-γ-butylolactone, 2.8 g of 2-methyladamantane-2-methacrylate, 2.3 g of 3-hydroxyadamantane-1-methacrylate, 0.12 g of butyl mercaptane, 0.53 g of dimethyl-2,2′-azobis(2-methylpropionate) and 12.2 g of tetrahydrofuran is prepared. The prepared solution is added dropwise for 4 hours to 8.6 g of tetrahydrofuran placed in flask with stirring and boiling under nitrogen atmosphere. After the addition of the prepared solution, the mixture is heated to reflux for 2 hours and cooled to room temperature. Addition of the mixture by drops to a mixed liquid containing 108 g of hexane and 12 g of tetrahydrofuran while vigorously stirring precipitates the copolymer. The copolymer is isolated by filtration. Purification of the copolymer is carried out by vacuum drying following two washings by 37 g of hexane, and, thereby, 5.8 g of white powder of the copolymer (Resin C) is obtained.

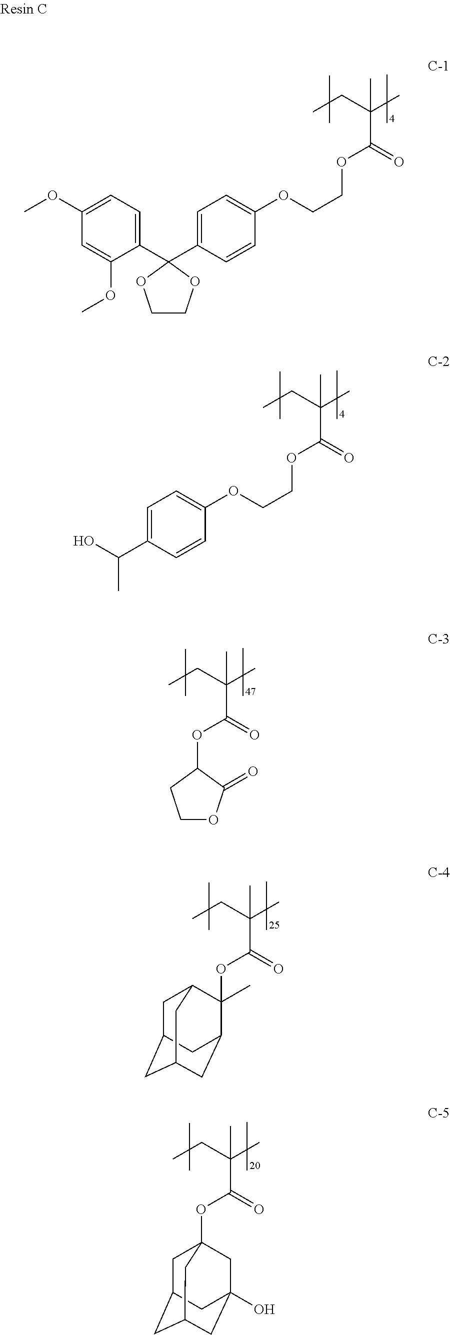 [SMILES: CCC(C)(C)C(=O)OCCOc1ccc(C2(c3ccc(OC)cc3OC)OCCO2)cc1 ; CCC(C)(C)C(=O)OCCOc1ccc(C(C)O)cc1 ; CCC(C)(C)C(=O)OC1CCOC1=O ; CCC(C)(C)C(=O)OC1(C)C2CC3CC(C2)CC1C3 ; CCC(C)(C)C(=O)OC12CC3CC(CC(O)(C3)C1)C2]

A solution containing 0.8 g of Monomer 1, 0.49 g of Monomer 2, 5.0 g of α-methacryloyloxy-γ-butylolactone, 3.0 g of 2-methyladamantane-2-methacrylate, 3.8 g of 3-hydroxyadamantane-1-methacrylate, 0.64 g of 5-phenyl-dibenzothiophenium 1,1-difluoro-2-(2-methyl-acryloyloxy)-ethanesulfonate, 0.17 g of butyl mercaptane, 0.70 g of dimethyl-2,2′-azobis(2-methylpropionate) and 14.3 g of tetrahydrofuran is prepared. 5-phenyl-dibenzothiophenium 1,1-difluoro-2-(2-methyl-acryloyloxy)-ethanesulfonate functions as a PAG moiety. The prepared solution is added dropwise for 4 hours to 6.0 g of tetrahydrofuran placed in flask while stirring and boiling. After the addition of the prepared solution, the mixture is heated to reflux for 2 hours and cooled to room temperature. Addition of the mixture by drops to a mixed liquid containing 126 g of hexane and 14 g of tetrahydrofuran while vigorously stirring precipitates the copolymer. The copolymer is isolated by filtration. Purification of the copolymer is carried out by vacuum drying following two washings by 44 g of hexane and two washings by methanol. Thereby, 6.1 g of white powder of the copolymer (Resin D) is obtained.

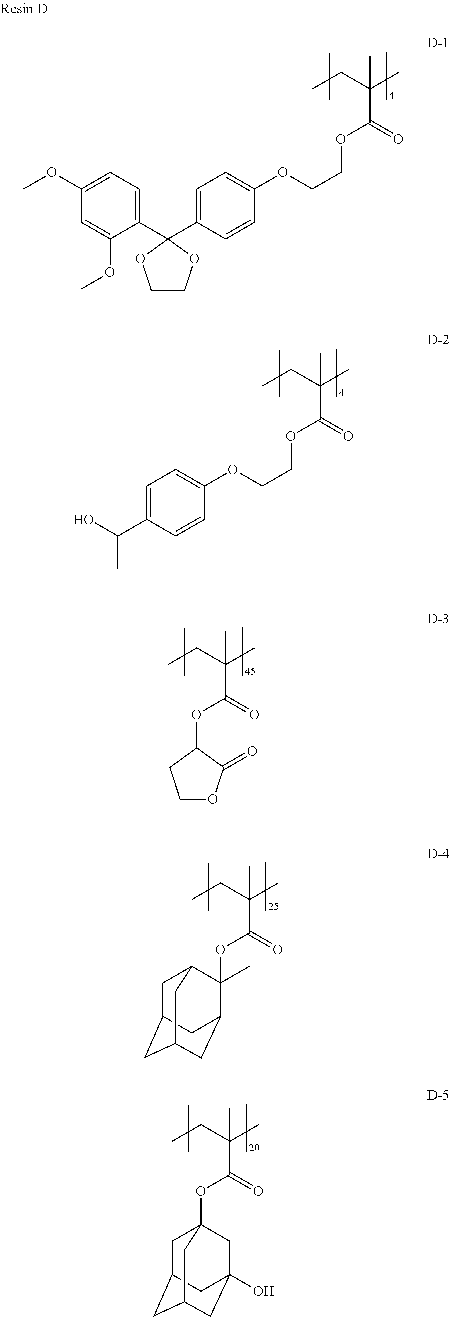 [SMILES: CCC(C)(C)C(=O)OCCOc1ccc(C2(c3ccc(OC)cc3OC)OCCO2)cc1 ; CCC(C)(C)C(=O)OCCOc1ccc(C(C)O)cc1 ; CCC(C)(C)C(=O)OC1CCOC1=O ; CCC(C)(C)C(=O)OC1(C)C2CC3CC(C2)CC1C3 ; CCC(C)(C)C(=O)OC12CC3CC(CC(O)(C3)C1)C2]

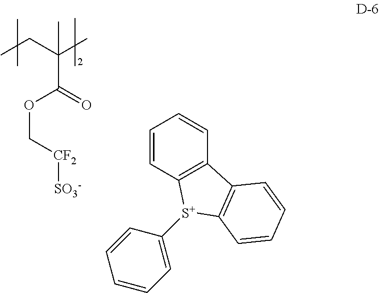

Preparation of Samples for Sensitivity Evaluation (the “Evaluation Samples”)

Evaluation Samples 1-13 are prepared by dissolving in 7000 mg of cyclohexanone at least five constituents among the following materials: (i) 0.043 mmol of a PAG selected from a group of consisting of diphenyliodonium nonafluorobutanesulfonate (DPI-PFBS) and phenyl dibenzothionium nonafluorobutanesulfonate (PBpS-PFBS); (ii) a resin selected from a group consisting of 500 mg of Resins A, 489 mg of B, 499 mg of C and 480 mg of D; (iii) at least one additive selected from a group consisting of Reagents mentioned above; (iv) 0.0043 mmol of trioctylamine as an acid quencher; (v) 0.50 mg of a surfactant agent containing fluorine atom; and (vi) 25 mg of DI-A as a dissolution inhibitor.

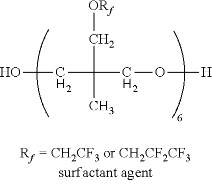

Reagent 1, C-2 moiety of Resin C and D-2 moiety of Resin D are generated by corresponding ketyl radicals by having their hydrogen atom on carbon atoms bonded to the hydroxy group abstracted by radicals formed by an electron beam (EB) or a EUV light. Each of such ketyl radicals donates an electron to the PAG to decompose the PAG. The PAG generates acid by the decomposition.

In other words, Reagent 1, C-2 moiety of Resin C and D-2 moiety of Resin D act as acid generation enhancer (AGE).

Reagent 1, B-1 moiety of Resin B, C-1 moiety of Resin C and D-1 moiety of Resin D are generated by corresponding ketones by deprotection reaction induced by acid. Such ketones can act as photosensitizers. In other words, the photosensitizers in their excited states donate electrons to PAGs to decompose the PAGs. The PAGs generate acid by the decomposition.

DPI-PFBS has higher electron acceptability than PBpS-PFBS.

TABLE 1
Constituents of Evaluation Samples for evaluating sensitivities

| | | | | | | Surfactant | Dissolution | |
|---|---|---|---|---|---|---|---|---|
| | Resin | PAG | Additive | | Quencher | agent | inhibitor | Solvent |
| Evaluation Sample 1 | Resin A | DPI-PFBS | — | | added | added | added | Cyclohexanone |
| Evaluation Sample 2 | | | Reagent 1 | | | | | |
| Evaluation Sample 3 | | | Reagent 2 | | | | | |
| Evaluation Sample 4 | | | Reagent 1 | Reagent 2 | | | | |
| Evaluation Sample 5 | | PBpS-PFBS | — | | | | | |
| Evaluation Sample 6 | | | Reagent 1 | | | | | |
| Evaluation Sample 7 | | | Reagent 2 | | | | | |
| Evaluation Sample 8 | | | Reagent 1 | Reagent 2 | | | | |
| Evaluation Sample 9 | | | | Reagent 3 | | | | |
| Evaluation Sample 10 | | | | Reagent 2 | — | | | |
| Evaluation Sample 11 | | | | | added | — | | |
| Evaluation Sample 12 | | | | | | added | — | |

| | | | | |
|---|---|---|---|---|
| Evaluation Sample 13 | Resin B | | — | added |
| Evaluation Sample 14 | | | Reagent 1 | |
| Evaluation Sample 15 | Resin C | | — | |
| Evaluation Sample 16 | Resin D | — | — | |

Before applying the Evaluation Samples to Si wafers, hexamethyldisilazane (HMDS, Tokyo Chemical Industry) is spin-coated at 2000 rpm for 20 seconds on the surfaces of Si wafers and baked at 110 degrees Celsius for 1 minute.

Then, the Evaluation Samples are spin-coated on the surfaces of the Si wafers, which have been treated with HMDS at 4000 rpm for 20 seconds, to form coating films. The prebake of the coating films is performed at 110 degrees Celsius for 60 seconds. Then, the coating films of the Evaluation Samples are exposed to 30 keV EB output from EB drawing system. Afterward, irradiations of the coating films with a UV light are carried out at an ambient condition.

After that the UV light exposure, a post-exposure-bake (PEB) is carried out at 110 degrees Celsius for 60 seconds. The coated films are developed with NMD-3 (tetra-methyl ammonium hydroxide 2.38%, Tokyo Ohka Kogyo) for 60 seconds at 25 degrees Celsius and rinsed with deionized water for 10 seconds. The thickness of the coating films measured using a film thickness measurement tool is approximately 150 nm. A sensitivity (E_{size}) is evaluated by measuring the dose size to form a pattern constituted by 100 nm lines where the thickness of the coating film is not zero and 100 nm spaces where the thickness of the coating film is zero using 30 keV EBL system JSM-7000F Beam Draw (JEOL) and FL-6BL (bright line is mainly from 350 nm to 400 nm, Hitachi), and UV dose for E_{size} is calculated by means of a measurement of illuminance of UV source by 365 nm illuminometer (USHIO UIT-150, UVD-S365). Moreover, surface roughness and pattern shape of patterned samples are observed by mean of scanning probe microscopy using SPM9600 (SHIMADZU).

TABLE 2
Total doses for E_{size} by EB and UV
exposure for Evaluation Samples

Total dose for E₀

| | EB dose | UV dose | Surface | Pattern |
|---|---|---|---|---|
| | [μC/cm²] | [mJ/cm²] | roughness | shape |
| Evaluation | 45.0 | 0 | flat | rectangle |
| Sample 1 | 45.0 | 200 | | |
| Evaluation | 37.5 | 0 | | |
| Sample 2 | 37.5 | 200 | | |
| Evaluation | 45.0 | 0 | | |
| Sample 3 | 22.5 | 200 | | |
| Evaluation | 40.0 | 0 | | |
| Sample 4 | 17.5 | 200 | | |
| Evaluation | 52.5 | 0 | | |
| Sample 5 | 52.5 | 200 | | |
| Evaluation | 45.0 | 0 | | |
| Sample 6 | 45.0 | 200 | | |
| Evaluation | 52.5 | 0 | | |
| Sample 7 | 22.5 | 200 | | |
| Evaluation | 45.0 | 0 | | |
| Sample 8 | 20.0 | 200 | | |
| Evaluation | 45.0 | 0 | | |
| Sample 9 | 40.0 | 200 | | |
| Evaluation | 40.0 | 0 | | shrinkage |
| Sample 10 | 17.5 | 200 | | |
| Evaluation | 45.0 | 0 | rough | rectangle |
| Sample 11 | 20.0 | 200 | | |
| Evaluation | 51.2 | 0 | flat | |
| Sample 12 | 23.8 | 200 | | |
| Evaluation | 52.5 | 0 | | |
| Sample 13 | 20.0 | 200 | | |
| Evaluation | 45.0 | 0 | | |
| Sample 14 | 17.5 | 200 | | |
| Evaluation | 43.8 | 0 | | |
| Sample 15 | 16.3 | 200 | | |
| Evaluation | 37.5 | 0 | | |
| Sample 16 | 11.3 | 200 | | |

Each of the Evaluation Samples 1-4 contains Resin A having groups to be deprotected by acid and DPI-PFBS as a PAG. Among them, the dose sizes measured for Evaluation Samples 2 and 4 containing Reagent 1 when UV irradiations are not carried out are small compared to the dose sizes of Evaluation Samples 1 and 3 not containing Reagent 1 when UV irradiations are not carried out. This indicates that ketyl radical generated by exposure of the films to the EB donates to the PAG to induce the decomposition of the PAG by which acid is generated.

Each of the Evaluation Samples 5-12 contains Resin A and PBpS-PFBS as a PAG. Among them, the dose sizes measured for Evaluation Samples 6 and 8-12 containing Reagent 1 when UV irradiations are not carried out are small compared to the dose sizes of Evaluation Samples 5 and 7 not containing Reagent 1 when UV irradiations are not carried out. This indicates that ketyl radical generated by exposure of Reagent 1 to the EB donates an electron to the PAG to induce the decomposition of the PAG by which acid is generated.

Each of the Evaluation Samples 13 and 14 contains Resin B and PBpS-PFBS as a PAG. Between them, the dose size measured for Evaluation Sample 14 containing Reagent 1 when no UV irradiation is carried out is small compared to the dose size of Evaluation Sample 13 not containing Reagent 1 when no UV irradiation is carried out. This indicates that ketyl radical generated by exposure of Reagent 1 to the EB donates an electron to the PAG to induce the decomposition of the PAG by which acid is generated.

The dose size measured for Evaluation Sample 15 containing Resin C instead of Reagent 1 when no UV irradiation is carried out is small compared to the doze size of Evaluation Samples 5 and 7. This indicates that C-2 moiety of Resin C acts as an AGE.

The dose size measured for Evaluation Sample 16 containing Resin D instead of Reagent 1 and a PAG when no UV irradiation is carried out is small compared to the doze size of Evaluation Sample 15 containing Resin C. Resin D has both D-6 acting as a PAG and D-2 moiety acting as an AGE in the same molecule, while Resin C has no PAG moiety.

In other words, a compound having both electron-donor and electron-acceptor or energy-donor and energy-acceptor in the same molecule enables improvement of efficiency of a reaction induced by electron transfer or energy transfer.

Therefore, in Resin D, ketyl radical formed by conversion of the AGE moiety is considered to easily donate an electron to the PAG moiety compared to Resin C.

Radicals are considered to be generated from Reagent 1, C-2 moiety of Resin C and D-2 of Resin D by having a hydrogen atom bonded to a carbon atom bonded to the hydroxy group abstracted. Such radicals can have reducing characters and reduce PAG even in their ground states.

These results concerning Evaluation Samples 2, 4, 6, 8-12 and 14-16 indicate that acid generation efficiencies is improved by reduction of PAG by such radicals generated from AGE or AGE moieties.

Instead of AGE or AGE moieties, derivatives having protection groups such as ether group, acetal group, acyl group and silyl ether group can be used. In that case, it is often desirable that such derivatives undergo deprotection.

Among the Evaluation Samples 1-4 containing Resin A having groups to be deprotected by acid and DPI-PFBS as a PAG, the dose sizes measured for Evaluation Samples 3 and 4 containing Reagent 2 when UV irradiations are carried out are strikingly small compared to the dose sizes of Evaluation Samples 1 and 2 not containing Reagent 2 when UV irradiations are carried out.

This indicates that ketones generated in situ through a deprotection reaction of Reagent 2 by acid formed by exposure of the coating film to the EB acts as photosensitizers suitable for the UV-light irradiation and the photosensitizers donate electrons to the PAG to induce the decomposition of the PAG by which acid is generated.

Among the Evaluation Samples 5-12 containing Resin A and PBpS-PFBS as a PAG, the dose sizes measured for Evaluation Samples 7, 8, 10, 11 and 12 containing Reagent 2 when UV irradiations are carried out are small compared to the dose sizes of Evaluation Samples 5, 6 and 9 not containing Reagent 2 when UV irradiations are carried out.

This also indicates that ketones generated in situ through a deprotection reaction of Reagent 2 by acid formed by exposure of the coating film to the EB act as photosensitizers suitable for the UV-light irradiation and the photosensitizers donate electrons to the PAG to induce the decomposition of the PAG by which acid is generated.

The dose size measured for Evaluation Samples 9 containing Reagent 3 of which deprotected derivative act as photosensitizer when an irradiation with a UV light following the EB exposures is carried out is slightly smaller than Evaluation Sample 5 containing none of Reagent 2 and Reagent 3. This is because the number of electron-donating substituents on the aromatic rings of Reagent 3 is small compared to Reagent 2. In other words, Reagent 3 has lower electron-donating ability compared to Reagent 2.

Each of the Evaluation Samples 13 and 14 contains Resin B and PBpS-PFBS as a PAG. The dose sizes measured for Evaluation Samples 13 and 14, both of which contain Reagent 2, when UV irradiations are carried out are small compared to the dose size of Evaluation Sample 5 containing none of photosensitizer like Reagent 2 and photosensitizing moieties like B-1, C-1 and D-1 when UV irradiation is carried out.

This indicates that B-1 moiety of Resin B is converted into a ketone moiety acting as photosensitizing moiety suitable the UV light by exposure of the coating films to the EB and the ketone moiety in its excited state donates an electron to the PAG to induce the decomposition of the PAG by which acid is generated.

The dose size measured for Evaluation Sample 15 containing Resin C when UV irradiation is carried out is small compared to the doze size of Evaluation Sample 5. This indicates that C-1 moiety of Resin C is converted into a corresponding ketone moiety acting as a photosensitizer suitable for the UV light.

The dose size measured for Evaluation Sample 16 containing Resin D instead of Reagent 2 and a PAG when UV irradiation is carried out is small compared to the doze size of Evaluation Sample 15. Resin D has both D-6 acting as a PAG and D-1 moiety acting as a precursor of photosensitizing moiety in the same molecule, while Resin C has no PAG moiety.

In other words, a compound having both electron-donor and electron-acceptor or energy-donor and energy-acceptor in the same molecule enables improvement of efficiency of a reaction induced by electron transfer or energy transfer.

Therefore, in Resin D, the photosensitizing moiety formed by conversion of D-1 moiety is considered to easily donate an electron to the PAG moiety compared to Resin C.

Incorporation of the moieties of B-1, C-1, C-2, D1 and D-2 moiety into resins enables homogeneous dispersion of photosensitizers or photosensitizing moieties. This may also contribute to improvement of sensitivity in acid generation efficiencies.

Such photosensitizers and photosensitizing moieties have at least two aromatic rings or two pi-electron systems interacting mutually more strongly compared to corresponding precursors and prodromal moieties. This is because such photosensitizers and photosensitizing moieties have a multiple bond connected to the at least two aromatic rings or two pi-electron systems, while interaction between the at least two aromatic rings or two pi-electron systems of the corresponding precursors and prodromal moieties is weaker.

The pattern shape evaluation for Evaluation Sample 10, which does not include quencher that can neutralize acid, shows pattern shrinkage. This is because absence of such quencher allows diffusion of acid.

In contrast, such pattern shrinkage is not clearly observed for the rest of Evaluation Samples containing quencher. This is because acid diffusion is suppressed due to quenching generated acid by quencher.

Typically, it is preferred that the concentration of quencher is 10 mol % for PAG for formation of 20-nm 1:1 lines and spaces and a pattern more finespun than that.

It is more preferable that the concentration of quencher is equal to or greater than 15 mol % for PAG to obtain such fine pattern with clearer rectangle shape because increase of quencher concentration can make bimolecular reaction between quencher and an electron donor such as ketyl radical and photosensitizer comparable to electron transfer from the electron donor.

Further, it is more preferable that the concentration of quencher is equal to or greater than 20 mol % for PAG to obtain such fine pattern.

The surface roughness evaluation for Evaluation Sample 11 containing the surfactant agent containing fluorine atoms shows large surface roughness. Low surface tension of a composition containing such surfactant agent can contribute to the flatness of the vapor-liquid interface of the composition disposed on a substrate.

In addition to this, the following mechanism contributes the flatness of the coating film. Evaporation rate of solvent or compound with a low molecular-weight of the composition disposed on the substrate is controlled since fluorine atoms of such surfactant agent are eccentrically located in the vicinity of the vapor-liquid interface of the composition disposed on a substrate. Therefore, flatness of the surface of the coating film is improved.

Incorporation of fluorine atoms into compositions increases the sensitivity to EB or EUV light and enhances acid generation efficiency. Addition of surfactant agent enhances formation of photosensitizer by deprotection reaction of protection group by acid as understood from comparison between Evaluation Sample 8 and Evaluation Sample 10.

The dose sizes measured for Evaluation Sample 12, which does not contain dissolution inhibitor DI-A, shows lower sensitivity. Dissolution inhibitor has at least one decomposable substituent by acid. At least one deprotected group is converted from the at least one decomposable substituent by acid while polymers having deprotected groups are formed from the resins by reaction between the resins and acid.

An interaction between the at least one deprotected group of DI-A and the deprotected polymers formed from the resins improve the solubility of the deprotected polymers. Therefore, the addition of DI-A improves apparent sensitivities of the coating film to the EB and lights.

This is understood from comparison between the result of Evaluation Sample 12 and that of Evaluations Sample 8, which is obtained under the same conditions as Evaluation Sample 12 except for the presence of DI-A shown in Table 1.

Evaluation of Sample Shelf Life

Evaluation Sample 17 is prepared by dissolving 0.00043 mmol of 3,5-di-tert-butyl-4-hydroxytoluene (BHT) as an oxidation inhibitor to Evaluation Sample 8. After that, Evaluation Sample 8 as a control sample and Evaluation Sample 17 have been stored for 2 weeks at 50 degrees Celsius under ambient atmosphere. Since then, the control sample and Evaluation Sample 17 are measured for sensitivity in accordance with the above-mentioned dose sizes measurement process.

TABLE 3
The shelf-life of Evaluation Samples

Total dose for E₀

| | EB dose | UV dose |
|---|---|---|
| | [μC/cm²] | [mJ/cm²] |
| Evaluation | 50.0 | 0 |
| Sample 8 | 22.5 | 200 |
| Evaluation | 45.0 | 0 |
| Sample 17 | 20.0 | 200 |

The shelf life evaluation of control sample shows sensitivity degradation by storing several days under ambient atmosphere. This result indicates that a small amount of Reagent 1 changes to ketone by aerial oxidation during the storage period.

On the other hand, E_{size} of Evaluation Sample 17 is nearly-unchanged compared to Evaluation Sample 8 shown in Table 2 owing to a small amount of the oxidation inhibitor. Therefore, an addition of oxidation inhibitor has efficacy for improving long-term stability of samples including an AGE.

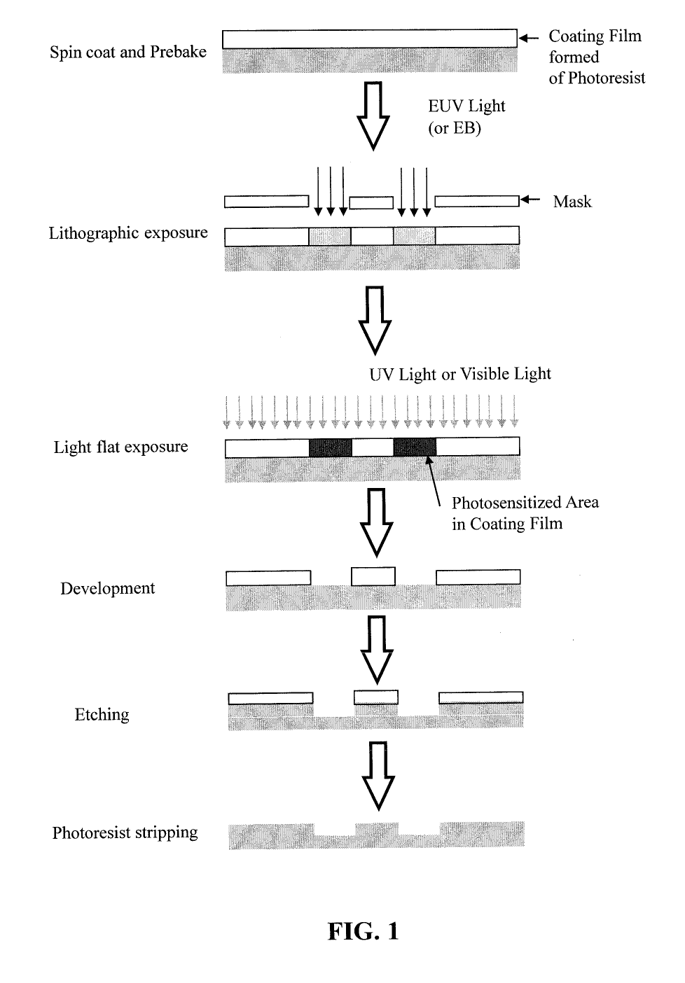

FIG. 1 shows fabrication processes of a device such as integrated circuit (IC) using a chemically amplified composition (CAR) photoresist including Resin A, PBpS-PFBS as a PAG, Reagent 1 and Reagent 2.

A silicon wafer is provided. The surface of the silicon wafer is oxidized by heating the silicon wafer in the presence of molecular oxygen.

A solution of the CAR photoresist is applied to the surface of the silicon wafer by spin coating to form a coating film. The coating film is prebaked.

An irradiation of the coating film with a EUV light through a mask is carried out after prebake of the silicon wafer.

The deprotection reaction of Reagent 2 contained in the CAR photoresist is induced by acid generated by exposure of the PAG to the EUV light and electron donation to the PAG from a ketyl radical formed from Reagent 1 by the EUV-light irradiation. Reagent 1 acts as an AGE.

Instead of the EUV light, EB is also used for the deprotection reaction of Reagent 2. In that case, mask may not be always used.

After the EUV irradiation of the coating film, an irradiation of the coating film with a light of which wavelength is equal to or longer than 300 nm is carried out without mask.

Development of the coating film that has been irradiated with the EUV light and the light of which wavelength is equal to or longer than 300 nm is performed after the prebake.

The coating film and the silicon wafer are exposed to plasma. After that, the remaining film is removed.

An electronic device such as integrated circuit is fabricated utilizing the processes shown in FIG. 1. The deterioration of the device due to the irradiation with a light is suppressed compared to existing photoresists since times for irradiation of the coating film is shortened.

What is claimed is:

1. A method of manufacturing a device, the method comprising:
forming a film containing a composition;
exposing the film to at least one of a first electromagnetic ray and a first particle ray; and
then exposing the film to at least one of a second electromagnetic ray and a second particle ray, wherein:
the composition includes a first reagent and a precursor; and
a chemical species is generated from the precursor at least one in the first exposing of the film and the second exposing of the film.

2. The method according to claim 1, wherein the first electromagnetic ray and the first particle ray are a EUV light and an electron beam, respectively.

3. The method according to claim 1, wherein the second electromagnetic ray is a UV light or a visible light.

4. The method according to claim 1, wherein the chemical species is acid.

5. The method according to claim 1, wherein the first exposing of the film generates a first chemical agent from the first reagent.

6. The method according to claim 5, wherein the first exposing of the film induces a first interaction of the precursor with at least one of the first reagent and the first chemical agent.

7. The method according to claim 5, wherein the first interaction occurs such that the first chemical agent donates at least one of electron and energy to the precursor or the first chemical agent accepts at least one of electron and energy from the precursor.

8. The method according to claim 5, wherein the first chemical agent is a ketyl radical.

9. The method according to claim 5, wherein the first chemical agent is a ketone.

10. The method according to claim 5, wherein the first chemical agent has at least one aryl group.

11. The method according to claim 10, wherein the at least one aryl group has at least one electron-donating substituent.

12. The method according to claim 5, wherein:
the first chemical agent absorbs at least one of the second electromagnetic ray and the second particle ray; and
the chemical species is generated at least during the second exposing of the film.

13. The method according to claim 1, wherein the composition further contains a quencher that traps the chemical species.

14. The method according to claim 13, wherein the quencher suppresses diffusion of the chemical species.

15. The method according to claim 1, wherein the second exposing of the film is carried out by using the second electromagnetic ray.

16. The method according to claim 1, wherein:
the first exposing of the film is carried out such that the film is irradiated with the first electromagnetic ray through a mask.

17. The method according to claim 16, wherein the second exposing of the film is carried out such that a portion of the film that has not been exposed to the first electromagnetic ray is irradiated with the second electromagnetic ray.

18. The method according to claim 15, wherein the second exposing of the film is carried out without any mask.

19. The method according to claim 1, wherein the composition further includes a resin having groups that are to react with the chemical species.

20. A composition, wherein the composition is suitable for performing the method according to claim 1.
